(19) United States
(12) Patent Application Publication
(10) Pub. No.: US 2025/0336749 A1
(43) Pub. Date: Oct. 30, 2025

(54) TEMPERATURE SENSING IN COMMON-DRAIN, BACK-TO-BACK POWER SWITCHES DEVELOPED IN VERTICAL FET TECHNOLOGY

(71) Applicant: Cypress Semiconductor Corporation, San Jose, CA (US)

(72) Inventors: Ramakrishna VENIGALLA, Bengaluru (IN); Santosh KULKARNI, Hubli (IN); Gerhard Thomas NÖBAUER, Villach (AT); Arun KHAMESRA, Bangalore (IN); Ankur ANCHLIA, Indore (IN)

(73) Assignee: Cypress Semiconductor Corporation, San Jose, CA (US)

(21) Appl. No.: 18/909,759

(22) Filed: Oct. 8, 2024

(30) Foreign Application Priority Data
Apr. 30, 2024 (IN) 2024411034338

(51) Int. Cl. H01L 23/34; G01K 7/01; H01L 27/088

(52) U.S. Cl. CPC H01L 23/34; G01K 7/01; H10D 84/83

(57) ABSTRACT

Techniques for temperature sensing in power FET switches are described. An example power field effect transistor (FET) device includes back-to-back power FETs coupled in series between a first power terminal and a second power terminal and connected to a common drain node. The power FET device also includes a temperature sense diode comprising a cathode coupled to the common drain node. A temperature sense circuit coupled to the power FET device is configured to determine a temperature of the first power FET and the second power FET based on a voltage drop across the temperature sense diode. The temperature sense circuit can include a voltage averaging circuit configured to sense a first voltage at the first power terminal, sense a second voltage at the second power terminal, and average the first voltage and the second voltage to generate a drain voltage representative of a voltage of the common drain node.

### PRIORITY

This application claims priority under 35 U.S.C. § 119(b) to Indian Patent Application No. 202411034338, filed Apr. 30, 2024, the entire contents of which is incorporated by reference herein in its entirety for all purposes.

### TECHNICAL FIELD

The present disclosure relates generally to the field of power delivery devices and systems and methods for controlling power delivery devices.

### BACKGROUND

Various electronic devices (e.g., such as smartphones, tablets, notebook computers, laptop computers, hubs, chargers, adapters, etc.) may be configured according to Universal Serial Bus (USB) power delivery protocols defined in various revisions of the USB Power Delivery (USB-PD) specification for wired charging through USB Type-C (USB-C) connectors. For example, in some applications an electronic device may be configured as a power consumer to receive power through a USB-C connector (e.g., a laptop for charging its own battery), while in other applications an electronic device may be configured as a power provider (e.g., a laptop) to provide power to another device (e.g., a smartphone) that is connected thereto through a USB-C connector. The USB-PD specification allows power providers and power consumers to dynamically negotiate various power levels, e.g., such as 5V (Volts) at 3 A (Amps), 15V at 3 A, 20V at 3 A, 12V at 5 A, 20V at 5 A, 48V at 5 A, etc. However, power delivery and control thereof is challenging in USB and other technologies that demand accurate power levels (e.g., voltage and/or current) and strict overvoltage, overcurrent, and overheating protections.

### BRIEF DESCRIPTION OF THE DRAWINGS

The disclosure is illustrated by way of example, and not of limitation, in the figures of the accompanying drawings.

FIG. 1 illustrates a circuit block diagram of a device for temperature sensing in a common-drain power field effect transistor (FET) device, according to some example embodiments of the present disclosure.

FIG. 2 illustrates a circuit block diagram of another device for temperature sensing in a common-drain power FET device, according to some embodiments of the present disclosure.

FIG. 3 illustrates a more detailed circuit block diagram of another device for temperature sensing in a common-drain power FET device, according to some embodiments of the present disclosure.

FIG. 4 illustrates an example structure of a vertical field effect transistor (FET) in accordance with some embodiments of the present disclosure.

FIG. 5 is a block diagram illustrating an integrated circuit (IC) controller that can be configured together with a power FET semiconductor device on a provider and/or consumer power path, in accordance with some embodiments of the present disclosure.

FIG. 6 is a block diagram illustrating a System-In-Package (SiP) including an IC controller and a power FET semiconductor device within a single package, in accordance with some embodiments of the present disclosure.

### DETAILED DESCRIPTION

The following description sets forth numerous specific details such as examples of specific systems, components, methods, and so forth, in order to provide a good understanding of various embodiments of the techniques described herein for temperature sensing in common-drain power FET switches implemented in vertical FET technology. It will be apparent to one skilled in the art, however, that at least some embodiments may be practiced without these specific details. In other instances, well-known components, elements, or methods are not described in detail or are presented in a simple block diagram format in order to avoid unnecessarily obscuring the techniques described herein. Thus, the specific details set forth hereinafter are merely exemplary. Particular implementations may vary from these exemplary details and still be contemplated to be within the spirit and scope of the present disclosure.

Reference in the description to “an embodiment,” “one embodiment,” “an example embodiment,” “some embodiments,” and “various embodiments” means that a particular feature, structure, step, operation, or characteristic described in connection with the embodiment(s) is included in at least one embodiment of the invention. Further, the appearances of the phrases “an embodiment,” “one embodiment,” “an example embodiment,” “some embodiments,” and “various embodiments” in various places in the description do not necessarily all refer to the same embodiment(s).

The description includes references to the accompanying drawings, which form a part of the detailed description. The drawings show illustrations in accordance with exemplary embodiments. These embodiments, which may also be referred to herein as “examples,” are described in enough detail to enable those skilled in the art to practice the embodiments of the claimed subject matter described herein. The embodiments may be combined, other embodiments may be utilized, or structural, logical, and electrical changes may be made without departing from the scope and spirit of the claimed subject matter. It should be understood that the embodiments described herein are not intended to limit the scope of the subject matter but rather to enable one skilled in the art to practice, make, and/or use the subject matter.

Described herein are various embodiments of techniques for temperature sensing in power FET devices for various USB-enabled electronic devices. Examples of such USB-enabled electronic devices include, without limitation, personal computers (e.g., laptop computers, notebook computers, etc.), mobile computing devices (e.g., tablets, tablet computers, etc.), mobile communication devices (e.g., smartphones, cell phones, personal digital assistants, messaging devices, pocket PCs, etc.), audio/video/data recording and/or playback devices (e.g., cameras, voice recorders, hand-held scanners, etc.), and other similar electronic devices that can use USB-C connectors for battery charging and/or power delivery.

Some USB-enabled electronic devices may be compliant with a specific revision and/or version of the USB-PD specification. The USB-PD specification defines a standard protocol designed to enable the maximum functionality of USB-enabled devices by providing more flexible power delivery along with data communications over a single USB-C cable through USB-C ports. The USB-PD specification also describes the architecture, protocols, power supply behavior, parameters, and cabling necessary for managing power delivery over USB-C cables at up to 100 W of power (or higher, up to 240 W, in case of Extended Power Range, or EPR). According to the USB-PD specification, devices with USB-C ports (e.g., such as USB-enabled devices) may negotiate for more current and/or higher or lower voltages over a USB-C cable than are allowed in older USB specifications (e.g., such as the USB 2.0 Specification, the USB Battery Charging Specification Rev. 1.1/1.2, etc.). For example, the USB-PD specification defines the protocol for negotiating a power delivery contract (PD contract) between a pair of USB-enabled devices. The PD contract can specify both the power level and the direction of power transfer that can be accommodated by both devices, and can be dynamically re-negotiated (e.g., without device un-plugging) upon request by either device and/or in response to various events and conditions, such as power role swap, data role swap, hard reset, failure of the power source, etc. According to the USB-PD specification, an electronic device is typically configured to deliver power to another device through a power path configured on a USB VBUS line. The device that provides power is typically referred to as (or includes) a “provider” (or a power source), and the device that consumes power is typically referred to as (or includes) a “consumer” (or a power sink). In some embodiments, a USB-PD power source can be configured to draw power from a direct current (DC) power source and can include a direct current-to-direct current (DC-DC) converter. In other embodiments, a USB-PD power source may be configured to draw power from an alternating current (AC) power adapter or from another AC source.

Power delivery and control thereof is typically challenging in USB-enabled and other technologies that demand accurate power levels (e.g., voltage and/or current) and strict overvoltage, overcurrent, and overheating protections. Electronic devices are typically configured to transfer power through Field Effect Transistors (FETs), or other similar switching devices. In some instances, the FETs may become susceptible to electrical damage (e.g., overcurrent damage, overvoltage damage, overheating damage, reverse current damage, and so forth) due to, for example, one or more electrical faults possibly occurring on the USB-C connector system. Power delivery IC controllers in such technologies typically struggle to meet the conflicting demands of accurate power levels, protection, and efficiency in high-current (e.g., 3 A, or above) implementations and applications.

An electronic device typically uses a power-transfer circuit (power path) to transfer power to/from the device. Among other electronic components, a power path may include one or more power FETs that are coupled in-line on the circuit path to operate as switches (e.g., as “ON”/“OFF” switches). Power FETs differ in some important characteristics from FETs and other types of transistor switch devices that are used for other, non-power-transfer applications. As a discrete semiconductor switching device, a power FET may carry a large amount of current between its source and its drain while it is “ON”, may have low resistance from its source to its drain while it is “ON”, and may withstand high voltages from its source to its drain while it is “OFF”. For example, a power FET may be characterized as being able to carry currents in the range of several hundred milliamps (e.g., 500-900 mA) to several amps (e.g., 3-5 A, or higher), and to withstand voltages in the range of 12V to 40V (or higher) across its source to its drain. For example, the resistance between the source and the drain of a power FET device may be very small in order to prevent, for example, the power loss across the device. The examples, implementations, and embodiments disclosed herein may use different types of FETs such as metal-oxide FETs (MOSFETs), nFETs (e.g., N-type MOSFETs), pFETS (e.g., P-type MOSFETS), etc.

The use of vertical FETs is a relatively new trend in integrated circuit design. Vertical FETs offer several advantages over traditional lateral FET designs such as higher current density, improved thermal performance, smaller device scale, and higher die-area efficiency, among others. Due to these advantages, vertical FETs are advantageous for high-density integrated circuits. However, vertical FETs present additional challenges with regard to temperature sensing.

In some implementations, temperature is sensed through a P-N diode fabricated in the power FET die in close proximity to the power FETs. Due to the linear temperature behavior of P-N diodes, their forward voltage (VF) directly relates to a certain temperature of the P-N diode under certain operating conditions. Accordingly, the temperature of the P-N diode can be determined by measuring the voltage drop across the P-N diode.

Typically for power FET's, the source and bulk terminals are indistinguishable. The P-N junction then becomes the drain and source/bulk terminals. However, to implement this temperature sensing approach involves measuring the voltage across the drain and bulk terminals. Accessing these nodes of the power FETs is relatively simple to achieve with lateral FETs, but is difficult to accomplish with vertical FETs. If back-to-back power FETs with a common drain are implemented in vertical FET technology, the conventional temperature sensing approach would demand various process technology changes or new custom package changes to enable access to the common drain (e.g., back-side metallization per die, etc.). However, such technology changes will increase costs and may even demand a new development cycle, which could be prohibitively expensive and time consuming.

To address these and other deficiencies of conventional temperature sensing in power FET devices, the techniques described herein provide temperature sensing techniques for a common-drain dual power FET device with vertical FETs. A power FET device in accordance with embodiments includes dual power FETs arranged in series and sharing a common drain node (i.e., back-to-back). A temperature sensing diode, e.g., in the form of a scaled P-N junction, is coupled to the common drain node. The anode of the diode is coupled to a temperature sense terminal enabling the voltage at the anode to be measured directly. The cathode of the temperature sensing diode is coupled to the common drain between the power FETs. Various techniques are described herein that enable the voltage at the common drain node to be determined despite the lack of direct access to the drain node.

In some embodiments, the voltage at the drain node is determined by measuring the voltage drop across the power path, which includes the input terminal coupled to the source of the first power FET and the output terminal coupled to the source of the second power FET. As long as both FETs are operating in the linear region as switches with their gate-to-source voltages much higher than their threshold voltages, the voltage drop across each FET will be equal, and the voltage across the input and output terminals can be measured and averaged to determine the voltage at the drain node.

In some embodiments, the voltage at the drain node is accessed through a replica FET. The power FET device may include one or more replica FETs fabricated within the same die, wherein a drain of each replica FET is coupled to the common drain node of the two power FETs. Various replica FETs may be implemented to enable various current sensing and voltage sensing features. One of the replica FETs (referred to herein as the temperature sense FET) is to provide a sense voltage representative of the voltage of the common drain node.

Each of these techniques for measuring the voltage at the drain has its own strengths and drawbacks. For example, sensing the voltage through a replica FET presents accuracy challenges due to the voltage drop across the replica FET. By contrast, the voltage averaging technique will be highly accurate as long as both of the power FETs are operating in the linear region. However, in some cases, a current limiting scheme may be used to reduce the gate drive signal provided to one of the power FETs. This increases the resistance of the affected power FET and limits the load current to the specified maximum current level. However, the affected power FET will no longer be operating in the linear region. Thus, the voltage drop across the power FETs will no longer be equal and voltage averaging will no longer provide an accurate reading of the drain voltage.

To address these drawbacks, both temperature sensing techniques may be implemented within the same package. When current limiting is not in effect, the voltage averaging technique can be used to determine the drain voltage. When current limiting is in effect, the drain voltage can be measured through the replica FET.

Embodiments of the present techniques also provide improvements to the fabrication of the temperature sense diode. In some embodiments, the P-N diode is fabricated as additional replica FET with the gate and the source terminals coupled together. When configured this way, the drain-to-bulk junction of the replica FET operates as a P-N diode. Fabricating the P-N diode as a replica FET as opposed to an explicit P-N diode reduces fabrication costs since it makes use of existing processes and masks.

The sensed voltage across the temperature sense diode can be digitized and processed (e.g., by an IC controller) to determine the temperature of the power FETs. The sensed temperature can be used (e.g., by firmware) to manage or discontinue the load current to protect against overheating.

In some embodiments, the techniques described herein provide for implementing such power FET devices in vertical FET technology, thereby improving power efficiency while allowing for delivery and control of higher currents than lateral FETs. However, it will be appreciated that although the disclosed techniques may be particularly well suited for power FET devices that include back-to-back vertical FETs with a common drain, the disclosed techniques are not limited to such embodiments. For example, the disclosed techniques can also be used with lateral FETs and FET devices that use a single power FET rather than dual power FETs.

In some embodiments, the techniques described herein also allow for implementing such a power FET device along with an IC controller die in a SiP package or dual-chip module. In some USB-enabled embodiments, the techniques described herein are compliant with common footprint definitions, making such embodiments readily available for design-in by vendors into various electronic devices such as laptops and notebooks.

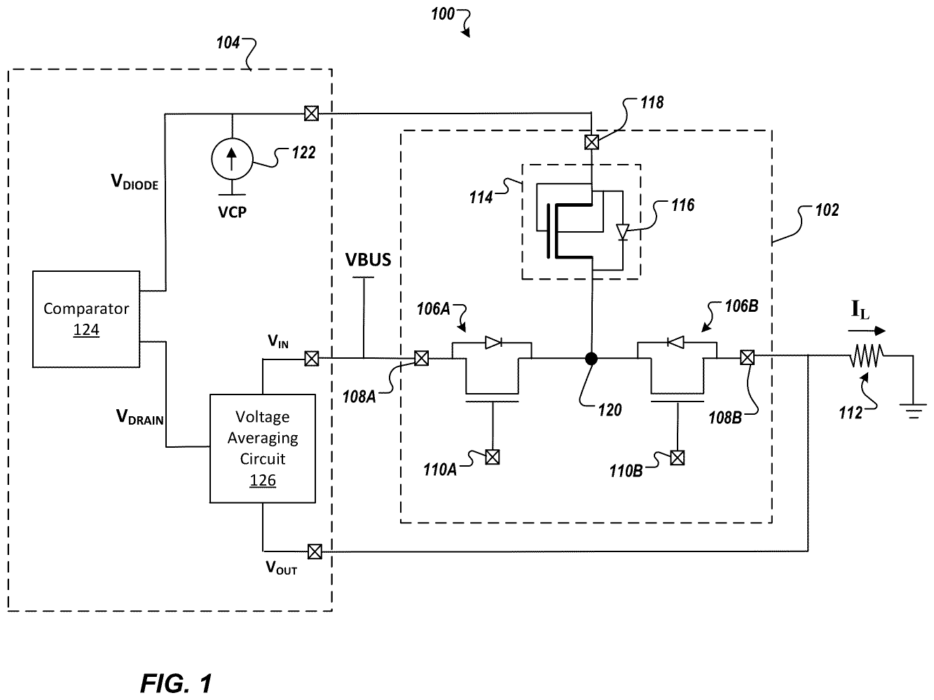

FIG. 1 illustrates a circuit block diagram of a device 100 for temperature sensing in a common-drain power FET device 102, according to some example embodiments of the present disclosure. The device 100 may include a power FET device 102 and a temperature sense circuit 104. In some embodiments, the power FET device 102 and a temperature sense circuit 104 may be instantiated on separate dies and enclosed in a single chip carrier package as a system in package (SiP) device.

The power FET device 102 is a power switch, instantiated on a single die, that includes two power FETs 106A and 106B coupled in series between power terminals 108A and 108B. According to the techniques described herein, the power FETs 106A and 106B are disposed back-to-back within power FET device 102, so in operation a load current, I_{L}, flows from the bus voltage, VBUS, to the load 112 as depicted. In addition, power FETs 106 are drain-connected to share a common drain node 120. The voltage at the common drain 120 may be referred to herein as V_{DRAIN}.

During operation, the gates 110A and 110B of the power FETs 106 are controlled by a gate driver (not shown) to turn on the power FETs 106A and 106B and thereby connect the bus voltage, VBUS, to the load 112 to provide current to the load 112. In some embodiments, the magnitude of the bus voltage may be determined in accordance with a power delivery (PD) contract as described above. The power FET device 102 is depicted as operating in a power delivery mode, in which case, the terminal 108A may be referred to as the input terminal 108A and the terminal 108B may be referred to as the output terminal 108B. However, the power FET device 102 can also be configured to operate in a power receiving mode, in which case the current through the power FETs 106A and 106B will be in the opposite direction relative to what is shown in FIG. 1.

The power FET device 102 also includes a temperature sense diode 114. In the embodiment shown in FIG. 1, the temperature sense diode 114 is a replica FET with the source and gate coupled together by a conductor. The replica FET 108 is an area-scaled versions of power FETs 106A and 106B. Coupling the source and gate together as shown in FIG. 1 causes the replica FET to operate as a P-N diode due to the bulk diode 116 (also referred to as a body diode) which is an intrinsic diode formed in FETs. It will be appreciated that the temperature sense diode 114 may be implemented using any suitable type of P-N diode, including other types of diode-connected transistors (e.g., a bipolar junction transistor with the collector and base coupled together), standard P-N junction diodes, and other configurations.

The cathode of the temperature sense diode 114 (i.e., the drain of the replica FET) is coupled to the common drain node 120, which can be accessed by fabricating the replica FET in linear mode or using simple contact masks. The anode of the temperature sense diode 114 is coupled to a temperature sense terminal 118 of the power FET device 102.

The temperature sense circuit 104 includes a current source 122, which is configured to provide a constant current of a known value to the temperature sense diode 114 through the temperature sense terminal 118. The temperature sense terminal 118 is also coupled to the input of a comparator 124, which is configured to determine the voltage difference between the temperature sense terminal 118 and the common drain node 120. The voltage at the temperature sense terminal 118 may be referred to herein as V_{DIODE}. The difference between the voltage at the temperature sense terminal 118 and the voltage at the common drain 120 is equal to the voltage drop across the temperature sense diode 114.

To determine the voltage at the common drain node 120, the power terminals 108A and 108B are coupled to a voltage averaging circuit 126, which generates an average of the input voltage (V_{IN}) at the input terminal 108A and the output voltage (V_{OUT}) at the output terminal 108B. The voltage drop across the temperature sense diode can then be determined using this average voltage as the drain voltage.

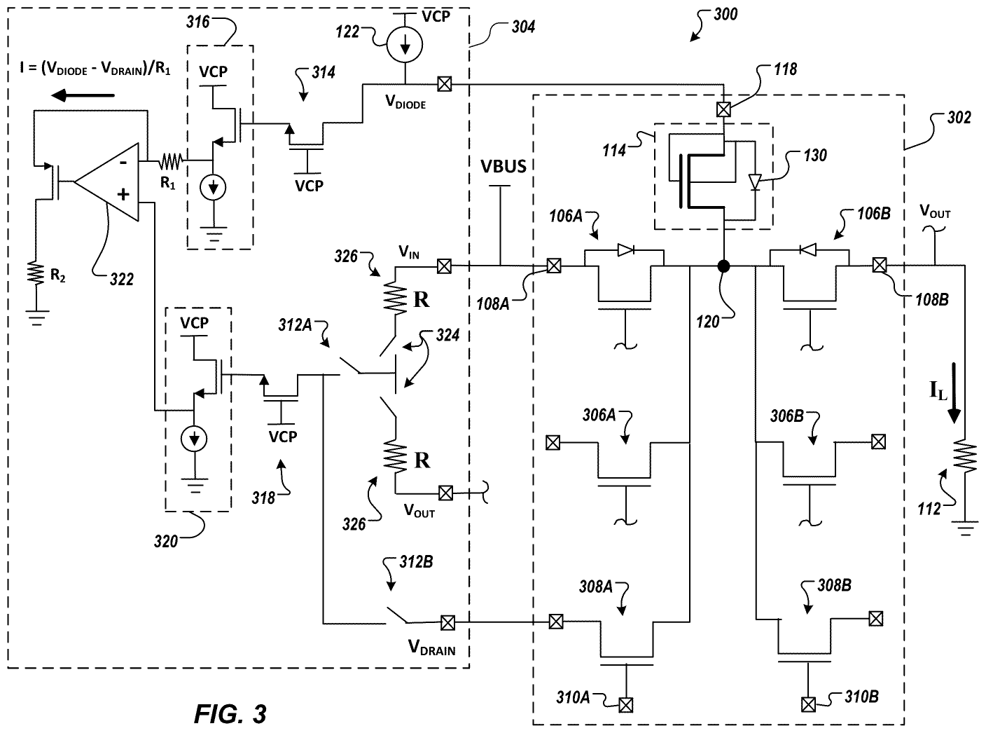

The voltage averaging circuit 126 may include any suitable type of circuitry for generating an average of two voltages. For example, the voltage averaging circuit 126 may be a resistor ladder (e.g., voltage divider) made up of two resistors of equal resistance, R, with the power terminals 108A and 108B coupled to opposite ends of the resistor ladder. An embodiment of a voltage averaging circuit 126 that includes a resistor ladder is shown in FIG. 3. If the voltage drop across both power FETs 106A and 106B is the same, then the average voltage output by the voltage averaging circuit 126 will be the same as the drain voltage, V_{DRAIN}. The drain voltage may be coupled to the input of the comparator 124. It will be appreciated that other techniques may be used to generate an average voltage. For example, in some embodiments, the input voltage and output voltage may be converted to digital values and the averaging may be performed in the digital domain. Thus, the voltage averaging circuit 126 may be implemented in one or more analog-to-digital converters, digital signal processors, microcontrollers, and combinations thereof.

The comparator 124 receives the two input voltages V_{DIODE} and V_{DRAIN} and determines the voltage drop across the temperature sense diode 114. The voltage drop may then be correlated with an equivalent temperature value. The comparator 124 can include any suitable combination of circuitry for performing the operations described herein. A more detailed example of a comparator is shown in FIG. 3. In some embodiments, the measured voltage drop across the temperature sense diode 114 may be digitized using an analog-to-digital converter (not shown) and processed to obtain a digital numerical value for the temperature. The value for the detected temperature may be used, for example, in a feedback loop that controls the bus voltage (VBUS) and/or gate driver (not shown) to limit or terminate the load current to avoid an overtemperature condition.

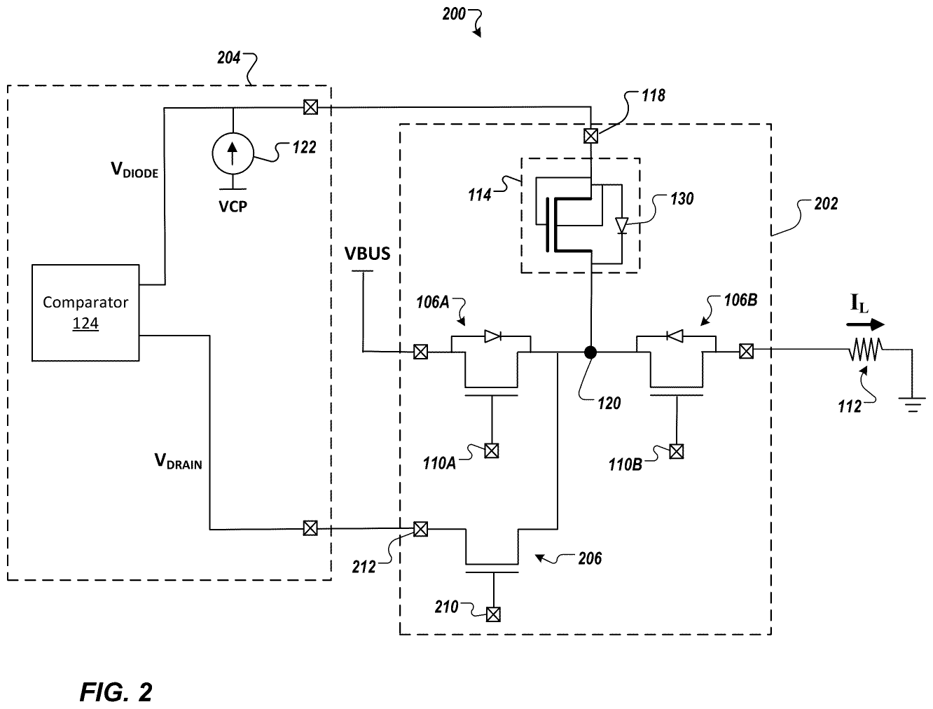

It will be appreciated that the circuit depicted in FIG. 1 is one example of a temperature sensing technique in accordance with embodiments, and that various modifications may be made without departing from the scope of the claims. Additional embodiments of the present techniques are described further in relation to FIGS. 2 and 3.

FIG. 2 illustrates a circuit block diagram of another device 200 for temperature sensing in a common-drain power FET device 102, according to some example embodiments of the present disclosure. The device 200 may include a power FET device 202 and a temperature sense circuit 204. The power FET device 202 illustrated in FIG. 2 is similar to the power FET device 202 of FIG. 1, except that the power FET device 202 includes a replica FET 206. The replica FET 206 is an area-scaled version of the power FETs 106A and 106B and is used to enable access to the voltage at the drain 120. The drain of replica FET 206 is coupled to the common drain node 120 and the source of the replica FET 206 is coupled to a voltage sense terminal 212 of the power FET device 202.

In the example shown in FIG. 2, the gates of the power FET 106A and the replica FET 206 may have separate gate terminals 110A and 210, respectively. However, in some embodiments, the gate of power FET 106A is connected internally to the gate of replica FET 206 so that they share a common gate terminal. It will further be appreciated that the power FET device 202 may include additional replica FETs not shown in FIG. 2.

The temperature sensing operates according to the same principle described above in relation to FIG. 1. A current source 122 is used to drive a specified current of a known value through the temperature sense diode 114, and the voltage drop across the temperature sense diode 114 is measured and converted to a temperature. As in FIG. 1, the voltage at the temperature sense terminal 118 (V_{DIODE}) is measured directly by the comparator 124. However, the drain voltage 120 is accessed through the replica FET 206. Activation of the replica FET 206 couples the drain node 120 to the voltage sense terminal 212, which is coupled to the input of the comparator 124. The comparator 124 receives the two input voltages V_{DIODE} and V_{DRAIN}, determines the voltage drop across the temperature sense diode 114, and converts the voltage to a corresponding temperature.

It will be appreciated that the circuit depicted in FIG. 2 is one example of a temperature sensing technique in accordance with embodiments, and that various modifications may be made without departing from the scope of the claims.

FIG. 3 illustrates a more detailed circuit block diagram of a device 300 for temperature sensing in a common-drain power FET device 302, according to some example embodiments of the present disclosure. The device 300 may include a power FET device 302 and a temperature sense circuit 304, which are configured to perform both temperature sensing techniques described above in relation to FIGS. 1 and 2.

The power FET device 302 illustrated in FIG. 3 is similar to the power FET device 202 of FIG. 2, except that the power FET device 302 includes additional replica FETs. Specifically, the power FET device 302 includes replica FETs 308A and 308B, which may be used for sensing the voltage of the drain node 120. The power FET device 302 includes replica FETs 306A and 306B, which may be used for additional applications that are beyond the scope of the present disclosure (e.g., current sensing, etc.). Any number of additional replica FETs may also be included.

Although not shown, the replica FETs may also include respective bulk diodes. The drains of each of the replica FETs, including the replica FET used for the temperature sense diode 114 and the replica FETs 306A, 306B, 308A, and 308B are also coupled to the same common drain node 120 as the two power FETs 106A and 106B. Thus, all seven FETs in the power FET device 302 share a common drain. The common drain node 120 can be accessed by fabricating the replica FETs in linear mode or using simple contact masks.

Additionally, in the example shown in FIG. 3, the gate of power FET 106A is connected internally to the gate of replica FET 306A and replica FET 308A so that they share a common gate terminal 310A. Similarly, the gate of power FET 106B is connected internally to the gate of replica FET 306B and replica FET 308B so that they share a common gate terminal 310B. For the sake of simplifying the illustration, the conductive connections between the respective gates are not shown. For purposes of the present description, the power FET 106A may be referred to as the input power FET 106A and the power FET 106B may be referred to as the output power FET 106B.

The device 300 combines the temperature sensing techniques describe above in relation to FIGS. 1 and 2. The technique for measuring the voltage at the drain node 120 (V_{DRAIN}) varies depending on whether current limiting is in effect. Although not shown, the device 300 may also be coupled to or include circuitry for limiting the current through the power FET device 302. For example, in a USB-enabled application, the current limit is dynamically determined by the PD contract established between the provider and the consumer. In such applications, a current limit may be determined using suitable firmware-controlled and/or programmable circuit (e.g., such as a circuit with controllable current source).

In some embodiments, current limiting may be implemented by limiting the magnitude of the gate signal provided to one of the gate terminals, e.g., gate terminal 310B. This, in turn, increases the resistance of the output power FET 106B and limits the load current, I_{L}, to the specified maximum current level. In this way, the current through the output power FET 106B can be limited, which effectively also limits the current through power FET device 302. At the same time, the gate signal provided to the gate terminal 310A may be unaffected by the current limiting circuitry. Thus, the input power FET 106A and the output power FET 106B will not be operating in the same manner and will not have an equal drain-to-source voltage drop. The drain-to-source voltage drop across the output power FET 106B will be higher since it is no longer operating in the linear region.

When current limiting is in effect, the drain voltage may be sensed through the replica FET 308A, as described in relation to FIG. 2. To receive the drain voltage from the replica FET 308A, the switch 312B is closed and the switch 312A is opened.

When current limiting is not in effect, the drain voltage (V_{DRAIN}) may be sensed by averaging the voltage across the power path, i.e., the voltage between the input terminal 108A (V_{IN}) and the output terminal 108B (V_{OUT}). The voltage averaging may be performed by the voltage averaging circuit 126 as described in relation to FIG. 1. In the embodiment shown in FIG. 3, the voltage averaging circuit is a resistor ladder (e.g., voltage divider) made up of two resistors 326 of equal resistance, R, with the power terminals 108A and 108B coupled to opposite ends of the resistor ladder. The resistance, R, of resistors 326 may be several times greater than the resistance of the power FETs 106A-B (e.g., 500 Ohms or more). The voltage at the center of the resistor ladder, i.e., between the resistors 326, will be the average of the voltage at the input terminal 108A (V_{IN}) and the voltage at the output terminal 108B (V_{OUT}). If the voltage drop across both power FETs 106A and 106B is the same, then the voltage at the center of the resistor ladder will be the same as the drain voltage, V_{DRAIN}. The drain voltage may be coupled to the input of the comparator 124.

For the sake of simplifying the illustration, the conductive connection between the voltage ladder and the output terminal 108B is not shown. However, it will be appreciated that the output terminal 108B is coupled to the resistor ladder as shown in FIG. 1. To receive the drain voltage from the voltage ladder, the switch 312B is opened and the switch 312A is closed. Additionally, in some embodiments, the resistor ladder may include a pair of switches 324 coupled between the resistors 326 as shown in FIG. 3. The resistors 324 can be used to prevent current between the input terminal 108A and the output terminal 108B when the resistor ladder is not in use. The switches 324 may be opened when switch 312A is opened and closed when switch 312A is closed.

FIG. 3 also shows additional details regarding an example implementation of the comparator 124 shown in FIGS. 1 and 2. The voltage sensed at the temperature sense terminal (V_{DIODE}) is transferred by FET 314 to a unity gain voltage buffer 316. The output of the voltage buffer 316 is coupled to the inverting input of an operation amplifier (op amp) 322 through a resistor, R1. The voltage, V_{DRAIN}, is transferred by FET 318 to another unity gain voltage buffer 320, the output of which is coupled to the non-inverting input of the op amp 322. The unity gain voltage buffers 316 and 320 transfer the respective voltages to the inputs of the op amp 322 while presenting a high input impedance so that the temperature sense circuit 304 does not load the circuitry of the power FET device 302.

The op amp 322 is configured as a closed-loop amplifier so that the current, I, through the resistor R₂ will be equal to (V_{DIODE}−V_{DRAIN})/R₁. The voltage across the sense resistor (R₂) can be measured and used as an indicator of the voltage drop across the temperature sense diode 114. In some embodiments, the voltage across the sense resistor (R₂) may be digitized using an analog-to-digital converter (not shown) and processed to obtain a numerical value for the detected temperature.

The power FET device 302 can also be configured to operate in a power receiving mode, in which case the current through the power FETs 106A and 106B will be in the opposite direction relative to what is shown in FIG. 3. If the power FET device 302 is operating in the power receiving mode, some functions may swap positions on the power FET device 302. For example, current limiting may be performed on the power FET 106A, which would become the output power FET. Additionally, if current limiting is in effect, the drain voltage may be sensed through the replica FET 308B. Accordingly, it will be appreciated that an additional conductor and switch can be used to couple the source terminal of the replica FET 308B to the temperature sense circuit 304.

It will be appreciated that the circuit depicted in FIG. 3 is one example of a temperature sensing technique in accordance with embodiments, and that various modifications may be made without departing from the scope of the claims.

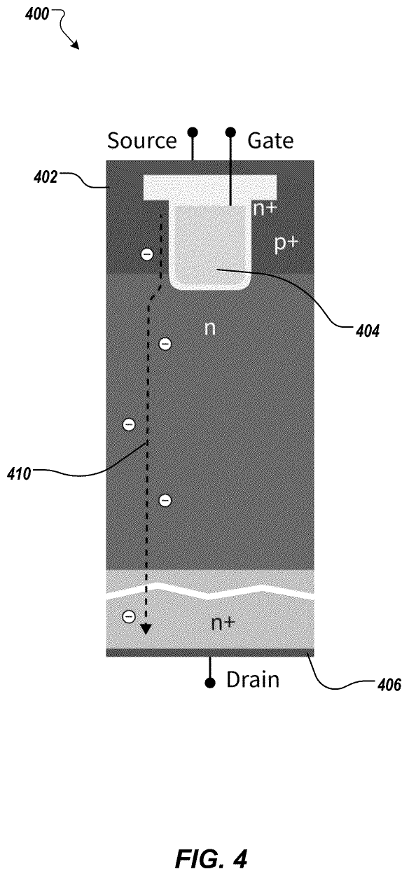

FIG. 4 illustrates an example structure of a vertical FET 400 in accordance with some embodiments. The vertical FET 400 shown in FIG. 4 may be referred to as a trench MOSFET. However, the current techniques may be suitable for any type of vertical FET, including Vertical MOSFETs (VMOS), vertical diffused MOSFETs (VDMOS), and others. Furthermore, embodiments of the disclosed techniques are not limited to the specific arrangement shown on FIG. 4, which is provided merely to present one example of vertical FET technology that may benefit from the disclosed techniques.

As shown in FIG. 4, the source 402 and the gate 404 are disposed on the top surface of the vertical FET 400 and the drain 406 is disposed on the bottom surface of the vertical FET 400 on the opposite side of the bulk semiconductor substrate compared to the source 402 and the gate 404. The direction of current flow is in the vertical direction from the source 402 to the drain 406 as indicated by the arrow 419. Typically, any additional vertical FETs fabricated in the same die will be oriented in similar fashion with the drain 406 on the bottom surface. Since the drain 406 is on the same semiconductor layer as the drains of any adjacent vertical FETs, it is relatively simple and cost efficient to fabricate two or more vertical FETs that share a connected/common drain. Vertical FETs such as the one depicted in FIG. 4 use much less lateral area compared to lateral FETs. Thus, such vertical FETs may be well suited for integrated circuit applications that benefit from higher circuit density.

However, since the drains of the vertical FETs are coupled to one another on the back side of the die, access to the drain may not be possible without additional processes, such as backside metallization and/or the development of additional masks and structures to bring out a drain connection to the top of the die. Such processes can add significant additional costs to the fabrication of the IC chip. Embodiments of the techniques disclosed herein enable temperature sensing techniques that either do not demand access the drain or enable access to the drain in a relatively cost-effective manner using scaled-down versions of other components on the die.

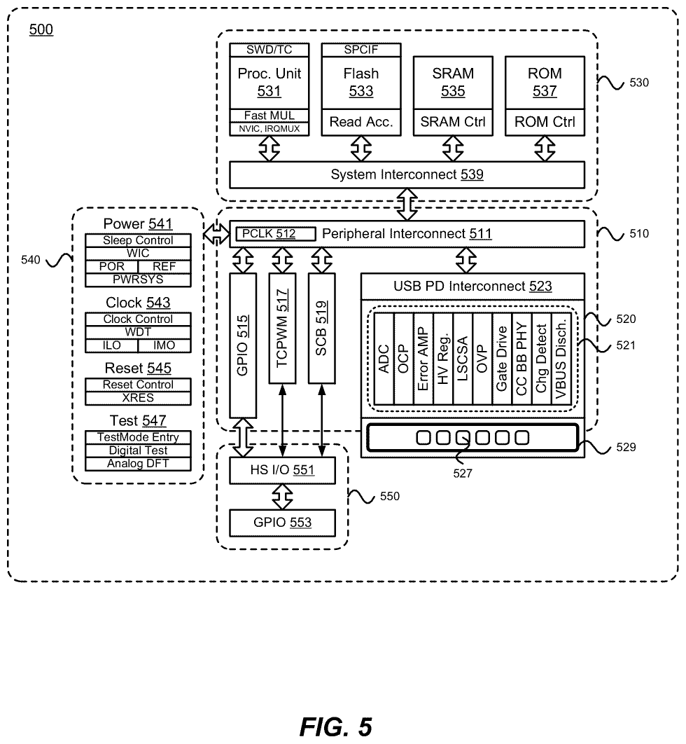

FIG. 5 is a block diagram illustrating an IC controller 500 that can be configured as a USB-PD controller together with a power FET semiconductor device on a provider and/or a consumer power path, in accordance with some embodiments. IC controller 500 may include a peripheral subsystem 510 including components for use in USB-PD power delivery. Peripheral subsystem 510 may include a peripheral interconnect 511 including a clocking module, peripheral clock (PCLK) 512 for providing clock signals to the various components of peripheral subsystem 510. Peripheral interconnect 511 may be a peripheral bus, such as a single-level or multi-level advanced high-performance bus (AHB), and may provide a data and control interface between peripheral subsystem 510, CPU subsystem 530, and system resources 540. Peripheral interconnect 511 may include controller circuits, such as direct memory access (DMA) controllers, which may be programmed to transfer data between peripheral blocks without input by, control of, or burden on CPU subsystem 530.

The peripheral interconnect 511 may be used to couple components of peripheral subsystem 510 to other components of IC controller 500. Coupled to peripheral interconnect 511 may be a number of general purpose input/outputs (GPIOs) 515 for sending and receiving signals. GPIOs 515 may include circuits configured to implement various functions such as pull-up, pull-down, input threshold select, input and output buffer enabling/disable, single multiplexing, etc. Still other functions may be implemented by GPIOs 515. One or more timer/counter/pulse-width modulator (TCPWM) 517 may also be coupled to the peripheral interconnect and include circuitry for implementing timing circuits (timers), counters, pulse-width modulators (PWMs) decoders, and other digital functions that may operate on I/O signals and provide digital signals to system components of IC controller 500. Peripheral subsystem 510 may also include one or more serial communication blocks (SCBs) 519 for implementation of serial communication interfaces such as inter-integrated circuit (I2C), serial peripheral interface (SPI), universal asynchronous receiver/transmitter (UART), controller area network (CAN), clock extension peripheral interface (CXPI), etc.

Peripheral subsystem 510 may include a USB power delivery subsystem 520 coupled to the peripheral interconnect and comprising a set of USB-PD modules 521 for use in USB power delivery. USB-PD modules 521 may be coupled to the peripheral interconnect 511 through a USB-PD interconnect 523. USB-PD modules 521 may include an analog-to-digital conversion (ADC) module for converting various analog signals to digital signals; an error amplifier (AMP) regulating the output voltage on VBUS line per a PD contract; a high-voltage (HV) regulator for converting the power source voltage to a precise voltage (such as 3.5-5V) to power IC controller 500; a high-side or low-side current sense amplifier (LSCSA) for measuring load current accurately, an over voltage protection (OVP) module and an over-current protection (OCP) module for providing over-current and over-voltage protection on the VBUS line with configurable thresholds and response times; one or more gate drivers for external power field effect transistors (FETs) used in USB power delivery in provider and/or consumer configurations; and a communication channel PHY (CC BB PHY) module for supporting communications on a USB-C communication channel (CC) line. USB-PD modules 521 may also include a charger detection module for determining that a charging circuit is present and coupled to IC controller 500 and a VBUS discharge module for controlling discharge of voltage on VBUS. The discharge control module may be configured to couple to a power source node on the VBUS line or to an output (power sink) node on the VBUS line and to discharge the voltage on the VBUS line to the desired voltage level (i.e., the voltage level negotiated in the PD contract). USB power delivery subsystem 520 may also include pads 527 for external connections and electrostatic discharge (ESD) protection circuitry 529, which may be required on a Type-C port. USB-PD modules 521 may also include a bi-directional communication module for supporting bi-directional communications with another controller.

GPIO 515, TCPWM 517, and SCB 519 may be coupled to an input/output (I/O) subsystem 550, which may include a high-speed (HS) I/O matrix 551 coupled to a number of GPIOs 553. GPIOs 515, TCPWM 517, and SCB 519 may be coupled to GPIOs 553 through HS I/O matrix 551.

IC controller 500 may also include a central processing unit (CPU) subsystem 530 for processing commands, storing program information, and data. CPU subsystem 530 may include one or more processing units 531 for executing instructions and reading from and writing to memory locations from a number of memories. Processing unit 531 may be a processor suitable for operation in an integrated circuit (IC) or a system-on-chip (SOC) device. In some embodiments, processing unit 531 may be optimized for low-power operation with extensive clock gating. In this embodiment, various internal control circuits may be implemented for processing unit operation in various power states. For example, processing unit 531 may include a wake-up interrupt controller (WIC) configured to wake the processing unit up from a sleep state, allowing power to be switched off when the IC or SOC is in a sleep state. CPU subsystem 530 may include one or more memories, including a flash memory 533, and static random-access memory (SRAM) 535, and a read-only memory (ROM) 537. Flash memory 533 may be a non-volatile memory (NAND flash, NOR flash, etc.) configured for storing data, programs, and/or other firmware instructions. Flash memory 533 may include a read accelerator and may improve access times by integration within CPU subsystem 530. SRAM 535 may be a volatile memory configured for storing data and firmware instructions accessible by processing unit 531. ROM 537 may be configured to store boot-up routines, configuration parameters, and other firmware parameters and settings that do not change during operation of IC controller 500. SRAM 535 and ROM 537 may have associated control circuits. Processing unit 531 and the memories may be coupled to a system interconnect 539 to route signals to and from the various components of CPU subsystem 530 to other blocks or modules of IC controller 500. System interconnect 539 may be implemented as a system bus such as a single-level or multi-level AHB. System interconnect 539 may be configured as an interface to couple the various components of CPU subsystem 530 to each other. System interconnect 539 may be coupled to peripheral interconnect 511 to provide signal paths between the components of CPU subsystem 530 and peripheral subsystem 510.

IC controller 500 may also include a number of system resources 540, including a power module 541, a clock module 543, a reset module 545, and a test module 547. Power module 541 may include a sleep control module, a wake-up interrupt control (WIC) module, a power-on-reset (POR) module, a number of voltage references (REF), and a power system (PWRSYS) module. In some embodiments, power module 541 may include circuits that allow IC controller 500 to draw and/or provide power from/to external sources at different voltage and/or current levels and to support controller operation in different power states, such as active, low-power, or sleep. In various embodiments, more power states may be implemented as IC controller 500 throttles back operation to achieve a desired power consumption or output. Clock module 543 may include a clock control module, a watchdog timer (WDT), an internal low-speed oscillator (ILO), and an internal main oscillator (IMO). Reset module 545 may include a reset control module and an external reset (XRES) module. Test module 547 may include a module to control and enter a test mode as well as testing control modules for analog and digital functions (digital test and analog DFT).

In some embodiments, IC controller 500 may be implemented in a monolithic (e.g., single) semiconductor die. According to the techniques described herein, in some embodiments the IC controller 500 die is disposed along with a power FET semiconductor die in a single package as a SiP or a single multi-chip module. The power FET die includes two back-to-back power FETs with a connected/common drain. The power FET die may also include a temperature sense diode coupled to the common drain and used to determine the temperature of the power FETs. The power FET die may also include respective replica FETs for sensing the voltage at the common drain. In such embodiments, peripheral subsystem 510 of IC controller 500 includes one or more gate drivers that are coupled (through respective terminals) to the FETs of the power FET die to control the power FETs therein in provider or consumer configurations and to activate the temperature sense diode for voltage/temperature sensing operations, in accordance with the techniques described herein. Additionally, the peripheral subsystem 510 of IC controller 500 may include any of the temperature sensing circuits 104, 204, and 304 described in relation to FIGS. 1-3. For example, the temperature sensing circuits 104, 204, 304 may be components of the USB-PD modules 521.

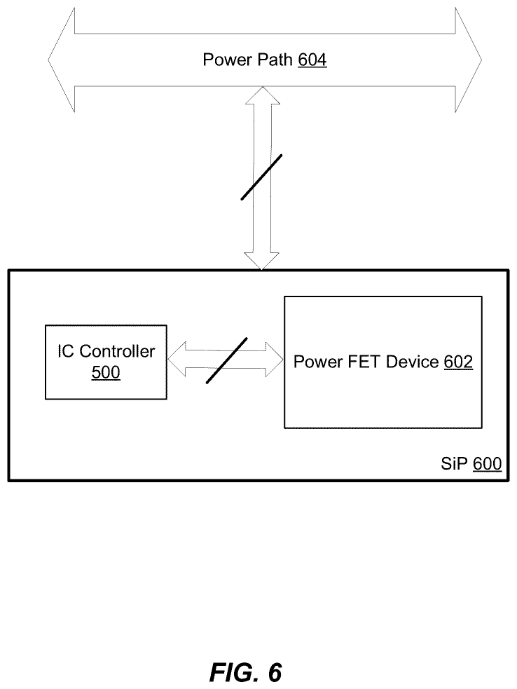

FIG. 6 is a block diagram illustrating a System-In-Package (SiP) 600 including an IC controller 500 and a power FET device 602 within a single package, in accordance with some embodiments. The power FET device 602 may be any one of the power FET devices 102, 202, and 302 described above in relations to FIGS. 1-3. Within SiP 600, various terminals of IC controller 500 are coupled over multiple metal lines (or bus) to the terminals of power FET device 602, in accordance with the techniques described herein. As illustrated, multiple pins of SiP 600 can be coupled to other components of a power path 604. In various implementations, power path 604 can be a provider power path (e.g., to provide power to a consumer) or a consumer power path (e.g., to receive power from a provider).

In the above description, some technical details may be presented in terms of algorithms and symbolic representations of operations performed by firmware and/or within a computer memory. These algorithmic descriptions and representations are the means used by those skilled in the data processing arts to most effectively convey the substance of their work to others skilled in the art. An algorithm is here and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as “determining”, “allocating,” “dynamically allocating,” “redistributing,” “ignoring,” “reallocating,” “detecting,” “performing,” “polling,” “registering,” “monitoring,” or the like, refer to the actions and processes of a device, or similar electronic system, that manipulates and transforms data represented as physical (e.g., electronic) quantities within the system's registers and memories into other data similarly represented as physical quantities within the system memories or registers.

The words “example” or “exemplary” are used herein to mean serving as an example, instance, or illustration. Any aspect or design described herein as “example’ or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “of” rather than an exclusive “or.” That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Moreover, use of the term “an embodiment” or “one embodiment” or “an embodiment” or “one embodiment” throughout is not intended to mean the same embodiment or embodiment unless described as such.

Embodiments descried herein may also relate to a device for performing the operations herein. Such device may be specially constructed for the intended purposes (e.g., an application-specific integrated circuit, ASIC), or it may be an integrated circuit (IC) including a CPU subsystem that can execute instructions stored as firmware in a non-transitory computer-readable storage medium. Such non-transitory computer-readable storage medium may include, but is not limited to, read-only memories (ROMs), random access memories (RAMs), erasable programmable read-only memories, (EPROMs), electrically erasable programmable read-only memories (EEPROMs), flash memory, or any type of media suitable for storing electronic instructions. The term “computer-readable storage medium” should be taken to include a single medium that stores one or more sets of instructions. The term “computer-readable medium” should also be taken to include any medium that is capable of storing, encoding, or carrying a set of instructions for execution by a device and that causes the device to perform any one or more of the methodologies of the present embodiments.

The above description sets forth numerous specific details such as examples of specific systems, components, methods, and so forth, in order to provide a good understanding of several embodiments of the present disclosure. It is to be understood that the above description is intended to be illustrative and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A device comprising:
a power field effect transistor (FET) device instantiated on a first die, the power FET device comprising:
a first power FET coupled to a first power terminal of the first die;
a second power FET disposed back-to-back with respect to the first power FET and coupled to a second power terminal of the first die, wherein the first power FET and the second power FET are connected to a common drain node within the first die; and
a temperature sense diode comprising a cathode coupled to the common drain node; and
a temperature sense circuit coupled to the power FET device and configured to determine a temperature of the first power FET and the second power FET based on a voltage drop across the temperature sense diode, the temperature sense circuit comprising a voltage averaging circuit coupled to a first voltage at the first power terminal and a second voltage at the second power terminal, wherein the temperature sense circuit is configured to average the first voltage and the second voltage to generate a drain voltage representative of a voltage of the common drain node.

2. The device of claim 1, wherein the voltage averaging circuit comprises a resistor ladder comprising a pair of resistors of equal resistance, wherein the first power terminal is coupled to a first end of the resistor ladder and the second power terminal is coupled to a second end of the resistor ladder.

3. The device of claim 1, wherein the drain voltage provided by the voltage averaging circuit is used to determine the voltage drop across the temperature sense diode when the first power FET and the second power FET are both operating in the linear region.

4. The device of claim 1, wherein the power FET device further comprises a replica FET, wherein a source of the replica FET is coupled to a voltage sense terminal of the first die and a drain of the replica FET is coupled to the common drain node, wherein the replica FET is configured to provide the drain voltage to the temperature sense circuit through the voltage sense terminal.

5. The device of claim 4, wherein the drain voltage provided by the replica FET is used to determine the voltage drop across the temperature sense diode if the first power FET or the second power FET is not operating in the linear region.

6. The device of claim 4, the temperature sense circuit further comprising a set of switches configured to:
couple the drain voltage provided by the voltage averaging circuit to a comparator when current limiting is not active; and
couple the drain voltage provided by the replica FET to the comparator when current limiting is active.

7. The device of claim 1, wherein the temperature sense diode comprises a replica FET with its source and gate coupled together and its drain coupled to the common drain node.

8. The device of claim 2, wherein the temperature sense circuit is included in an integrated circuit (IC) controller instantiated on a second die.

9. The device of claim 8, wherein the IC controller is configured as a Universal Serial Bus Power Delivery (USB-PD) controller.

10. The device of claim 8, wherein the power FET device and the IC controller are disposed within a single semiconductor package as a System-in-Package (SiP).

11. The device of claim 1, wherein the first power FET and the second power FET are vertical FETs.

12. A power field effect transistor (FET) device comprising:
a first power FET and a second power FET arranged in series and electrically coupled through a common drain node, wherein the first power FET and the second power FET are configured to deliver an output current to a load responsive to a first gate drive signal coupled to the first power FET through a first gate terminal of the power FET device, and a second gate drive signal coupled to the second power FET through a second gate terminal of the power FET device;
a temperature sense diode to indicate a temperature of the first power FET and a second power FET, the temperature sense diode comprising a cathode coupled to the common drain node and an anode coupled to a temperature sense terminal; and
a replica FET to provide a sense voltage corresponding to a voltage of the common drain node, wherein the first power FET, the second power FET, and the replica FET are vertical FETs.

13. The power FET device of claim 12, wherein a gate of the replica FET is conductively coupled to the first gate terminal of the first power FET.

14. The power FET device of claim 12, wherein the replica FET is a first replica FET configured to provide the sense voltage corresponding to the voltage of the common drain node when the power FET device is operating in power provider mode, the power FET device further comprising:
a second replica FET to provide the sense voltage corresponding to the voltage of the common drain node when the power FET device is operating in power receiving mode.

15. The power FET device of claim 12, wherein the temperature sense diode comprises an additional replica FET with its source and gate coupled together and its drain coupled to the common drain node.

16. The power FET device of claim 12, wherein the power FET device is instantiated on a first die disposed within a semiconductor package as a System-in-Package (SiP), wherein the semiconductor package further comprises an integrated circuit (IC) controller instantiated on a second die.

17. The power FET device of claim 16, wherein the integrated circuit (IC) controller further comprises:
a temperature sense circuit to determine a temperature of the power FET device based on a voltage drop across the temperature sense diode.

18. The power FET device of claim 17, wherein when current limiting is active, the temperature sense circuit is configured to:
determine the voltage drop across the temperature sense diode using the sense voltage provided by the replica FET as the voltage of the common drain node.

19. The power FET device of claim 17, wherein when current limiting is not active, the temperature sense circuit is configured to:
generate an average voltage comprising an average of an input voltage at a first power terminal coupled to a source of the first power FET and an output voltage at a second power terminal coupled to a source of the second power FET; and
determine the voltage drop across the temperature sense diode using the average voltage as the voltage of the common drain node.

20. The power FET device of claim 16, wherein the IC controller is configured as a Universal Serial Bus Power Delivery (USB-PD) controller.
